(19) United States
(12) Patent Application Publication
(10) Pub. No.: US 2024/0397674 A1
(43) Pub. Date: Nov. 28, 2024

(54) METHOD FOR PRODUCING A COOLING DEVICE

(71) Applicant: Miba Sinter Austria GmbH, Laakirchen (AT)

(72) Inventors: Manuel POHN, Lenzing (AT); Michael BUCHEGGER, Vorchdorf (AT); Matthias GRAFINGER, Gmunden (AT); Julian MAIER, Vorchdorf (AT)

(73) Assignee: Miba Sinter Austria GmbH, Laakirchen (AT)

(21) Appl. No.: 18/669,839

(22) Filed: May 21, 2024

(30) Foreign Application Priority Data
May 22, 2023 (AT) A50397/2023

(51) Int. Cl. H05K 7/20; B22F 3/16; B22F 3/20; B22F 5/00; H01L 23/367

(52) U.S. Cl. CPC H05K 7/209; B22F 3/16; B22F 3/20; B22F 5/00; H01L 23/3677; B22F 2003/202; B22F 2998/10

(57) ABSTRACT

A method for producing a cooling device includes the steps of providing a material and forming a cooling structure from the material, a sinter powder being used as the material, from which a green compact is produced by pressing, the green compact being sintered into a preform, and the cooling structure in the form of cooling elements being produced from the preform by forming, for which a part of the preform is pressed through a forming tool, forming being carried out in a plurality of forming steps.

### CROSS REFERENCE TO RELATED APPLICATIONS

Applicant claims priority under 35 U.S.C. § 119 of Austrian Application No. A50397/2023 filed May 22, 2023, the disclosure of which is incorporated by reference.

### BACKGROUND OF THE INVENTION

### 1. Field of the Invention

The invention relates to a method for producing a cooling device, comprising the steps of providing a material and forming a cooling structure from the material.

The invention further relates to a cooling device for cooling components, comprising a base element having a first surface, and with a cooling structure having cooling elements, which is arranged on the base element so as to project beyond the first surface.

### 2. Description of the Related Art

What are known as power electronics components, such as power semiconductors, are sufficiently known from the prior art. Such components are often used in motor vehicles, for example. It is also known that these components generate large amounts of heat during operation, which often require the help of a cooling medium to dissipate. A wide variety of coolers for this purpose are known in the prior art.

For example, DE 11 2007 000 829 B4 describes an arrangement of an inverter and a cooler for cooling the inverter, the cooler comprising the following: a substrate having a surface on which the inverter is disposed, heat dissipation components attached to another opposite surface of the substrate and surrounding an area opposite an area in which the inverter is arranged on the one surface of the substrate, a main pipe remote from the other surface of the substrate and defining a space between the main pipe and the substrate, and which is configured to be fed with a coolant and to allow the coolant to contact the heat dissipation components; and a secondary pipe projecting from the main pipe toward the substrate and facing the region of the substrate in which the inverter is disposed so as to impinge on the other surface of the substrate at the region facing the region in which the inverter is disposed with a coolant fed to the main pipe, wherein the coolant supplied to the main pipe is separated from the coolant supplied to the area until it is expelled from the secondary pipe.

What are known as pin fin heat sinks have also been described in the prior art, which are flushed with a cooling medium and transfer the heat from the pins to the cooling medium in this manner. DE 10 2019 108 106 A1, for example, describes a cooler for a power semiconductor in an inverter, wherein the cooler is configured in two parts and comprises: a base plate as a first part, which can be connected to the power semiconductor in a thermally conductive manner, a heat sink as a second part, which is arranged on the base plate, wherein the heat sink has at least one undulating recess, which is formed continuously from a side of the heat sink facing away from the base plate to a side facing the heat sink, wherein the first and second parts are connected to one another and are coated by means of a layer that protects both parts from electrochemical reduction.

DE 10 2018 216 859 A1 discloses a device for cooling components, comprising: a first and a second base body, cylindrical and/or conical first cooling ribs, around which a coolant can flow, which are formed in the first base body, and cylindrical and/or conical second cooling ribs, around which the coolant can flow, which are formed in the second base body, the second cooling ribs being joined to the first base body in such a way that the second cooling ribs come to lie between the first cooling ribs without touching the first base body.

Cooling devices for power electronics often have a structure of structural elements on their surface. In order to increase the cooling performance, it is advantageous to have as high a surface area of the structural elements as possible around which a cooling fluid can flow. However, this is limited by the mechanical strength of the structural elements, since the structural elements can only be reduced to a minimum size. By reducing the size of the structural elements, more structural elements can be arranged per unit area, meaning that the cooling performance can be improved due to the larger surface area provided thereby.

### SUMMARY OF THE INVENTION

The problem to be solved of the present invention is to improve the cooling performance of a cooling device for components, the cooling device to be produced in a resource-saving manner.

The problem of the invention is solved by the method mentioned at the outset, according to which it is provided that a sintered powder is used as the material, from which a green compact is produced by pressing, that the green compact is sintered to form a preform, and that the cooling structure in the form of cooling elements is produced from the preform by forming, for which a part of the preform is pressed through a forming tool, the forming being carried out in a plurality of forming steps.

Furthermore, the problem of the invention is solved with the cooling device mentioned in the introduction, in which the base element and the cooling elements are composed of a sintered material and the cooling elements are produced from the material of the base element by multi-stage forming.

The advantage thereof is that, as a result of forming the base element into the cooling elements for the production thereof, no waste material is produced, as is the case in machining, for example. In addition, all cooling elements of the cooling device can be manufactured at the same time, thus achieving a corresponding increase in productivity. For forming, it is advantageous that the preform, though it already has corresponding strength due to sintering, can be formed more easily due to pores compared to a solid material. The multi-stage forming process enables the provision of cooling elements with a larger surface area, which can improve the cooling performance of the cooling device. For example, multi-stage forming can provide undercut cooling elements or cooling elements that generally change in cross section.

According to a preferred embodiment of the invention, it can be provided that the height of the cooling elements above a base element of the cooling structure is increased with at least two of the plurality of forming steps, thereby increasing the surface area available for cooling. The multi-stage nature enables a cooling structure with relatively thin cooling elements without exposing the cooling elements to a significantly increased risk of damage during forming, for example due to cracks, etc. It is thus still possible to achieve a large/the same number of cooling elements per unit area, yet the cooling elements can be or are configured to be higher.

According to a further embodiment of the invention, it can be provided that the same forming tool is used for at least two of the plurality of forming steps. Forming can be made more economical or the forming movement sequence can be simplified with this embodiment.

According to another embodiment of the invention, heat treatment of the cooling device can be carried out between at least two of the plurality of forming steps. This enables the subsequent forming step to be carried out more gently on the tool.

According to an embodiment of the invention, it can be provided that the preform is re-compressed and that the cooling structure is partially formed during the re-compression. By combining these steps into a single method step, the production time of the cooling device can be correspondingly shortened. It is advantageous that, due to the fact that the preform has not been re-compressed in advance, its first forming step to form the cooling structure can be carried out more easily on account of a higher pore proportion.

According to a further embodiment of the invention, it can be provided that the cooling structure is produced by using a perforated plate as a forming tool or a plurality of perforated plates as forming tools in the form of pin-shaped cooling elements. The forming tool or tools can thus be configured in a relatively simple manner. In addition, it can easily be adapted to different cooling element shapes. Surprisingly, despite the large contact area, demolding the cooling elements by pulling off the perforated plate(s) does not pose a problem with regard to material chipping, etc.

According to a further embodiment of the invention, it can be provided that the cooling device is calibrated after the forming steps for producing the cooling elements. The tolerance of the cooling elements can thus be reduced with a method that is simple in execution.

According to another embodiment of the invention, it can be provided that the height of the cooling elements is adjusted by pressing material out of the head region of the cooling elements into a region adjacent to or below the head region of the cooling elements. Using a sintered material is also advantageous in this case, since this makes it easier to compress the material in the head region of the cooling elements due to residual pores. The height of the cooling elements, in particular the same height of the cooling elements except for tolerances, can thus be adjusted easily and quickly without machining.

According to another embodiment of the invention, the base element and the cooling elements can have a density of at least 98% of the full density of the material used, as a result of which the cooling device can have improved corrosion properties even without further post-treatment, despite powder metallurgical production. This is particularly advantageous for the cooling elements around which a coolant flows during operation.

According to another embodiment variant of the invention, it can be provided that the cooling elements have a height above the first surface of the base element between 4 mm and 40 mm. With regard to the formability, these heights of the cooling elements have proven to be advantageous, since the material flow over the entire height of the cooling elements can thus be made more uniform even in the case of multi-stage forming.

According to an embodiment of the invention, it can be provided that a rear side of the base element is configured with a flat surface, such that the contact of the base element on the one hand during forming against a punch and on the other hand against a component to be cooled can be improved during operation of the cooling device.

According to a further embodiment of the invention, it can be provided that at least one further structural element is arranged on the first surface of the base element, which protrudes beyond the cooling elements in the direction of the height, and which is produced in net-shape or near net-shape quality. The powder-metallurgical production of the cooling device is also advantageous in this case, since further planes can be produced on the cooling device without complex machining, as these are already taken into account in the original forming for the production of the preform.

According to a further embodiment of the invention, it can be provided that at least some of the cooling elements in the head region have a higher density than the other cooling elements and/or that at least some of the cooling elements in the head region are a different shape to the other cooling elements. Cooling elements can be provided in this manner that can be better adapted to the respective field of application. In this case, multi-stage forming is again advantageous, since all cooling elements of a cooling device can be produced with simpler tools.

### BRIEF DESCRIPTION OF THE DRAWINGS

Other objects and features of the invention will become apparent from the following detailed description considered in connection with the accompanying drawings. It is to be understood, however, that the drawings are designed as an illustration only and not as a definition of the limits of the invention.

In the drawings,

FIG. 1 shows a side view of a cooling device with a component to be cooled;

FIG. 2 shows an oblique view of a cooling device;

FIG. 3 shows an embodiment of a preform;

FIG. 4 shows an embodiment of a tool for producing the cooling device;

FIG. 5 shows an embodiment of a sequence of method steps for producing a cooling device with multi-stage forming; and

FIG. 6 shows a detail of a tool for adjusting the height of the cooling elements.

### DETAILED DESCRIPTION OF PREFERRED EMBODIMENTS

It is worth noting here that the same parts have been given the same reference numerals or same component designations in the embodiments described differently, yet the disclosures contained throughout the entire description can be applied analogously to the same parts with the same reference numerals or the same component designations. The indications of position selected in the description, such as above, below, on the side etc. refer to the figure directly described and shown, and these indications of position can be applied in the same way to the new position should the position change.

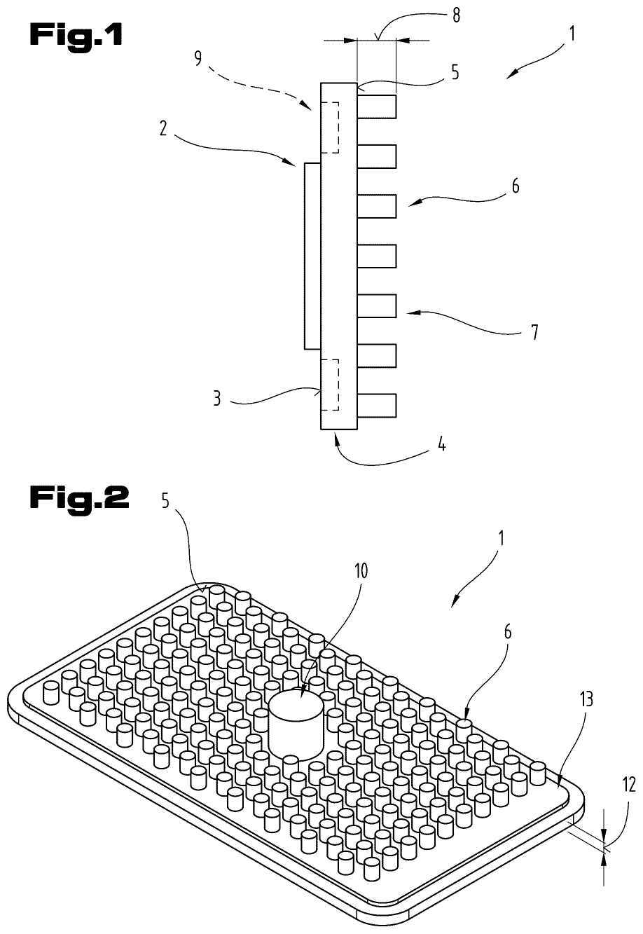

FIG. 1 shows a side view of a cooling device 1.

The cooling device 1 is used to cool a component 2 or a plurality of components 2 or an assembly. For this purpose, the cooling device 1 bears with a rear side 3 against the at least one component 2 in particular directly, i.e. is preferably in direct contact with the component 2 for heat exchange.

The component 2 is preferably an electronic component, in particular what is known as a power electronics component or high-power electronics component or a power semiconductor or high-power semiconductor but can also be configured differently. In particular, such components 2 or assemblies of/with these components 2 can be provided for power in the range from several kW to MW. Such components 2 are used for transforming electrical energy with switching electronic components, for example. Typical applications are converters or frequency converters in the field of electric drive technology, solar inverters and converters for wind turbines for feeding regeneratively generated energy or switched-mode power supplies into the grid, generally the conversion of AC voltage into DC voltage by rectifiers, the conversion of DC voltage into AC voltage by inverters, controllers, for example in the drive technology of an electric drive in electric vehicles or hybrid vehicles, battery management systems, etc. A power electronics component can be, for example, a semiconductor, in particular a what is known as a power semiconductor, e.g. an IGBT.

Since such components 2 are known from the relevant prior art per se, reference is made to this prior art to avoid repetition with regard to details.

The cooling device 1 comprises a base element 4, which also forms the rear side 3 of the cooling device 1 and which has a cooling structure on a first surface 5 or consists of the base element 4 and the cooling structure. The cooling structure is formed by cooling elements 6, which are arranged protruding beyond the first surface 5 on the base element 4 and are integrally connected thereto, as can also be seen from FIG. 2. In other words, in the preferred embodiment, the cooling device is formed by only a single part. Irrespective of the one-piece configuration, within the scope of the invention, it is possible for a plurality of cooling devices 2 to be combined with one another to form a cooling device group per component 2 or assembly composed of/with at least one such component 1 according to the invention. In particular, a plurality of cooling devices 1 can therefore also be assembled in modular fashion to form a cooling device group.

The base element 4 and the cooling elements 6 are made or are composed of a sintered material. Furthermore, the cooling elements 6 are produced from the base element 4 by forming.

In the preferred embodiment, the base element 4 and the cooling elements 8 have a density of at least 98%, in particular at least 98.5%, preferably at least 99% of the full density of the material used.

Full density refers to the density of a cooling device made of the same material by fusion metallurgy, i.e. a component made of a solid material. Solid material here means a metallic material which, with the exception of defects, has no pores, as is usually the case with sintered components.

Provision is made for a cooling fluid, for example water, to flow around the cooling elements 6 so that the heat absorbed by the cooling device 1 is transported away via this cooling fluid. The cooling device 1 is preferably what is known as a pin fin cooling device.

The cooling elements 6 of the embodiment depicted are cylindrical. However, they can also be a different shape, for example frustoconical or generally a cross-section tapering in the direction of a cooling element head 7, for example a frusto-pyramidal cross-section. According to an embodiment, several or all cooling elements 6 in the head region can be mushroom shaped, as indicated by dashed lines in FIG. 6.

The cross section of the cooling elements 6 can be circular, oval, diamond shaped, square, etc.

Furthermore, all cooling elements 6 can be configured identically. However, it is also possible to arrange or combine cooling elements 4 of different shapes on or with a base element 6.

The cooling elements 6 can preferably have a height 8 above the first surface 5 of the base element 4 that is between 4 mm and 40 mm.

In the simplest embodiment of the cooling device 1, all cooling elements 6 of the cooling device 1 have the same height 8 within tolerance limits. However, within the scope of the invention, it is possible for some of the cooling elements 6 to have a lower height than the other cooling elements 6.

Furthermore, it can be provided that cooling elements 6 are arranged or formed per dm² of the first surface area between 300 and 1300, in particular between 300 and 1000, for example between 300 and 750. This number in particular has proven to be advantageous with regard to the production of the cooling device 1, i.e. forming the base element 4 into the cooling elements 6, since damage to the cooling elements 6 or incompletely formed cooling elements 6 can thus be avoided or reduced.

As can be seen in particular from FIG. 1, according to one embodiment of the cooling device 1, it can be provided that the rear side 3 of the base element 4 is configured to have a planar surface. However, it is also possible for the rear side 3 to be formed with one or more depressions 9, in which a component 2 is at least partially received. This permits better connection of the component 2 to the cooling device 1. In general, the component 2 can be glued or screwed or soldered or sintered, etc., to the cooling device 1, for example.

The at least one depression 9 can be produced simultaneously with the cooling elements 6 during their production. It is also possible to produce cooling elements 6, whose height 8 is greater than that of the other cooling elements 6, by the at least one recess 9.

As can be seen from FIG. 2, the cooling device 1 can have at least one further structural element 10 on the first surface 5 of the base element 4. In the shape shown, the structural element 10 is a cylinder, but can also have a different cross-sectional area, for example diamond shaped. With the structural element 10, a further surface 11 can be provided on the cooling device 1, which lies above the plane of the cooling elements 6. The structural element 10 can thus have a greater height than the cooling elements 6. However, it is also possible for the at least one structural element 10 to have a lower height or the same height as the cooling elements 6. Furthermore, more than one structural element 10 can be arranged, wherein the plurality of structural elements 10 can be configured identically or differently, e.g. in terms of shape and/or height.

The structural element 10 can be provided, for example, for a screw connection, as stiffeners or as a spacer or as a stop.

The structural element 10 is preferably not mechanically finished, but rather co-pressed or produced by powder metallurgy in net shape or near net shape quality during the pressing of a preform for the production of the cooling device 1. The structural element 10 or the structural elements 10 are therefore preferably formed integrally with the base element 4 and the cooling elements 6.

To produce the cooling device 1, a sintered powder or a powder used in powder metallurgy, in particular a metallic powder, is used. Preferably, a sinter powder with correspondingly good thermal conductivity is used. In particular, a sinter powder based on aluminum or an aluminum alloy or based on copper or a copper alloy or an MMC powder (metal matrix composite) is used.

The cooling device is produced by powder metallurgy according to a powder metallurgy process, i.e. the cooling device 1 is preferably a sintered component. For this purpose, a green compact is manufactured in a corresponding mould (die) from a sintered powder, which can be produced from the individual (metallic) powders by mixing, wherein the powders used can optionally be pre-alloyed. The green compact preferably has a density of at least 80%, in particular between 80% and 96% of the full density of the material.

The green compact can subsequently be dewaxed at customary temperatures and sintered in one, two or more stages and then preferably cooled to room temperature. Sintering can take place at a temperature between 500° C. and 1300° C., for example.

Since these processes and the process parameters used are also known from the prior art, reference to the relevant prior art is made in this regard in order to avoid repetition.

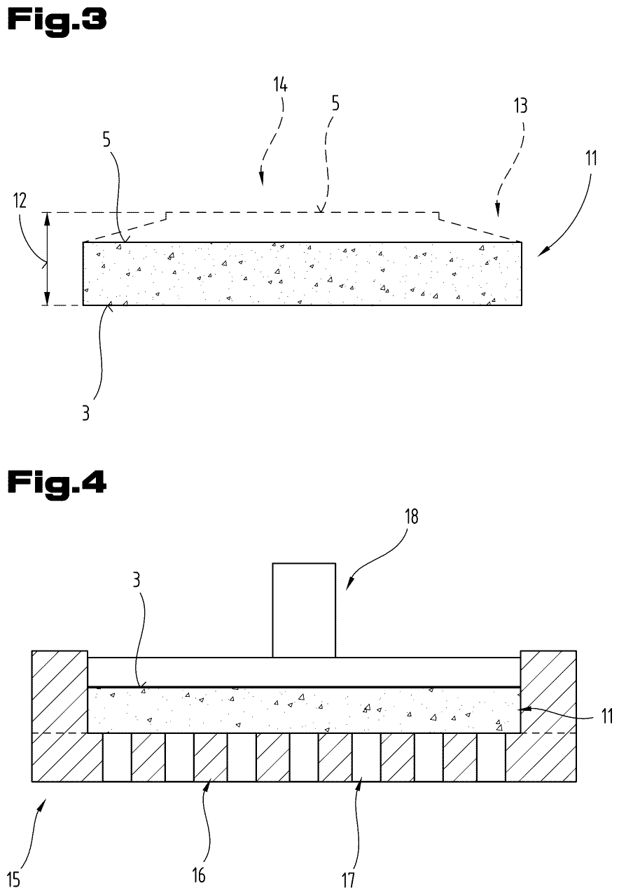

The sintering produces a preform 11 from the green compact, as shown by way of example in FIG. 3. The preform 11 can be configured as a flat plate or plate-shaped so that the rear side 3 and at least a section of the first surface 5 can extend parallel to one another.

According to an embodiment of the method, it can be provided that the first surface 5 of the preform 11, upon which the cooling structure is formed, is produced at least in sections in a curved manner. In general, the preform 11 can be produced at least in sections with a different thickness 12. In particular, the preform 11 can be produced thinner in at least one edge section 13 or in a plurality of edge sections 13 than in a central section 14, as shown by dashed lines in FIG. 3. The central section 14 is the region of the preform 11 with the greatest thickness 12. The thinner edge sections 13 can, for example, be formed circumferentially around the central section 14, i.e. along the entire circumference of the central section 14. The reduction in thickness 12 can be discontinuous and/or ramp-shaped starting from the central portion 14, as is also shown in FIG. 3. Other shapes are also possible.

The reduced thickness 12 in at least one edge portion 13 can also still be present in the finished cooling device 1, as shown in FIG. 2.

Other shapes of the first surface of the preform 11 are possible with regard to improved formability of the preform 11. In this way, first pin fin attachments or cooling element attachments (circular, oval, elliptical, etc.) with a height between 0.1 mm and 2.0 mm can already be preformed. In addition, structures (corrugations, ribs, etc.) can be deliberately introduced into the surface 5 of the preform in order to increase swirling of a cooling fluid, if necessary.

The preform 11 can subsequently be re-compressed. Preferably, however, re-compression takes place at the same time as the forming of the preform 11 into the cooling elements 6.

The forming of the preform 11 takes place in a forming tool 15. For this purpose, the preform 11 is inserted into the forming tool 15 or placed against it. In the simplest case, the forming tool 15 is formed by a perforated plate 16. The perforated plate 16 has recesses 17, in particular apertures, into or through which a part of the material of the preform 11 is pressed, thereby forming the cooling elements 6. The remainder of the material of the preform 11, which is not pressed into or through the forming tool 15, forms the base member 4.

The recesses 17, i.e. their cross section, are correspondingly adapted to the cross section of the cooling elements 6 to be produced.

The forming tool 15 can also look different, i.e. it does not necessarily have to be a simple perforated plate 16. In particular, the forming tool 15 can be configured as a “cup-shaped” die.

In the event that at least one further structural element 10 is present, this can be accounted for by a corresponding recess or a corresponding opening in the forming tool 15.

For forming, a punch 18 can be placed against the rear side 3, of the preform 11, which also forms the rear side 3 of the base element 4 and is pressed onto the preform 11 with a pre-determinable pressure. As a result of the pressure exerted onto the preform 11, material of the preform 11 is pressed into the recesses 17 or apertures of the forming tool 15. Forming can take place at a pressure between 700 MPa and 1600 MPa, for example. Furthermore, forming can take place for up to 10 seconds of time, in particular between 0.1 seconds and 10 seconds. Furthermore, forming preferably takes place at room temperature (20° C.), i.e. cold, or forming can also take place after preheating the preform 11 to a temperature between 50° C. and 300° C., for example between 50° C. and 150° C., and/or in/with a forming tool 15 heated to a temperature between 50° C. and 300° C., for example between 50° C. and 150° C.

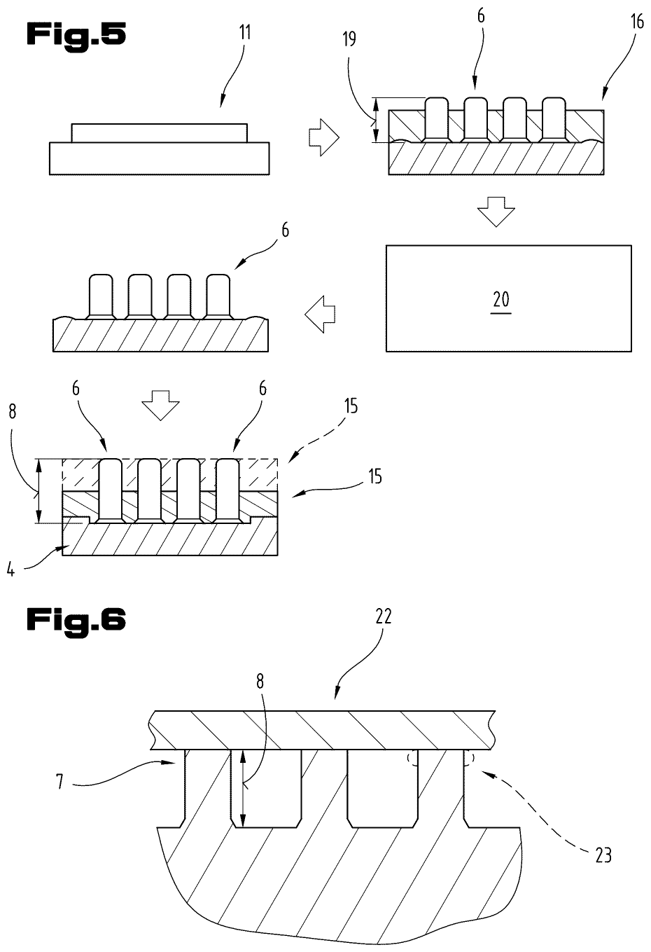

It is provided that forming of the preform 11 into the cooling structure or into the cooling device 1 is carried out in several stages, i.e. in two or more steps, as shown schematically in FIG. 5 with reference to a forming method with two forming steps. However, it should be mentioned that the method for producing the cooling device 1 can also have more than two forming steps, for example three or four or five, etc., with which the cooling elements 6 are formed.

It is mentioned at this point that multi-stage forming means the forming of the preform 11 into the cooling elements 6 and not other forming that can also be carried out, such as calibrating the cooling elements 6, for example, as will be explained below.

Multi-stage forming can be carried out in the individual forming steps with at least approximately constant degrees of forming. The cooling elements 6 can undergo at least approximately the same height change in each of the forming steps, for example. However, it is also possible for the degrees of forming to differ from one another in the individual forming steps. For example, the change in height of the cooling elements 6 in a first forming step can be greater than in a subsequent forming step, or conversely, the change in height of the cooling elements 6 in a first forming step can be smaller than in a subsequent forming step.

The forming parameters can be the same or different in the individual forming steps. For example, the pressure exerted on the preform 11 can be greater in a first forming step than in a subsequent forming step. The forming parameters can be selected from the aforementioned ranges in the individual forming steps.

For the two-stage forming method shown by way of example in FIG. 5 for forming the cooling elements 6, the cooling elements 6 are formed in a first forming step from the preform 11 with the forming tool 15, for example the perforated plate 16 mentioned, with a first partial height 19. The first partial height 19 is smaller than the height 8 of the cooling elements 6 after the second forming step, as can be seen in FIG. 5. The partial height 19 can be in the range between 20% and 80% of the height 8, for example.

Thus, using this method, the height 8 of the cooling elements 6 above a base element 4 of the cooling structure is increased with at least two of the plurality of forming steps. For this purpose, the method can have exactly two forming steps for forming the height with a forming tool 15, for example the perforated plate 16, or more than two such forming steps. This means that the word “plurality” can also mean only “two” in the wording “with at least two of the plurality of forming steps”.

The same forming tool, i.e. the forming tool 15, for example the perforated plate 16, can be used for the second forming step or, in general, for at least two of the plurality of forming steps, so that after the first forming step, the partially formed cooling elements 6 are pressed again through or into the forming tool 15 of the preceding forming stage. However, it is also possible to use two or more identical forming tools 15, for example perforated plates 16. However, it is also possible to carry out forming with different forming tools 15, using forming tools 15, whose recesses 17 have different diameters, for example. Different forming tools 15 can also be used in the individual forming steps to form undercuts in or projections on the cooling elements 6, or at least some of the plurality of cooling elements 6 of the cooling device 1.

In the depiction of the embodiment of a method sequence of the invention according to FIG. 5, a forming tool 15 is illustrated in the second step, which is configured in the same way as the forming tool 15 of the first forming step. Dashed lines indicate that the forming tool 15 of the second forming stage can also have a greater layer thickness, in particular a layer thickness that is at least approximately equal to the height 8 of the cooling elements 6 at the end of this forming step in order to create support for the section of the cooling elements 6 already formed in the second or further forming step.

The two forming steps or at least two of the plurality of forming steps can be carried out in separate forming tools 15. However, a method is also possible, in which the two forming steps or at least two of the plurality of forming steps can be carried out in a separate forming tool 15. This forming tool 15 can have a cross-section of the recesses 17 that tapers in the direction of the material flow during forming. The taper can be continuous or discontinuous. If necessary, a tool stage with cross-sectional widening can be formed between two discontinuously changing cross-sectional dimensions in order to achieve relief in the material formed in the preceding forming step. The individual steps of the multi-stage forming tool 15 can have the same height as or a different height from one another. Stepped cooling elements 6 can be produced with such a configuration of the forming tool 15. If necessary, the stages can be further formed with a further forming tool 15 in a further forming step as required, in order to produce cooling elements 6 that have no change in cross section when viewed over their height, that is to say are configured to be cylindrical, for example.

The method sequence according to FIG. 5 shows a further embodiment of the invention. In this case, it can be provided that heat treatment of the cooling device is carried out between the two forming steps or at least two of the plurality of forming steps or between all of the forming steps. The heat treatment can be carried out in a furnace 20, for example a continuous furnace. Other heat sources can also be used. The heat treatment can be carried out inductively, for example. The inductive heat treatment can also heat treat only defined zones, in particular in the region of the cooling elements 6 partially formed in the preceding forming.

The heat treatment can be carried out at a temperature between 100° C. and 500° C., the specific temperature depending on the sintered material used and its melting point. The heat treatment can also be carried out as intermediate sintering, i.e. re-sintering, of the already partially formed preform 11.

The heat treatment can also achieve that the region of the cooling elements 6 formed in the preceding forming step becomes softer again, so that the forming step following heat treatment can be carried out more easily.

After forming, i.e. the forming of the preform 11, the cooling device 1 can be complete. However, it is also possible to finish the cooling device 1.

After forming, i.e. the forming of the preform 11, the cooling device 1 can be calibrated. Calibrating increases the dimensional accuracy of the cooling device 1 at least in sections or in areas. In addition, by calibrating, the pores in the area of the calibrated surface can be closed, such that a denser structure can be achieved. During calibration, the cooling structure, in particular at least some of the cooling elements 6, are thus exposed to pressure on their respective surface(s).

According to a preferred embodiment, a height calibration of the cooling elements 6 can be carried out as shown in FIG. 6. In this case, the cooling element heads 7, can be pressed from above with a calibrating tool 22, which can be plate-shaped or punch-shaped, for example. During this process, the cooling device 1 can be held in a holding element, such as a die. The height deviation can decrease in the direction of the central section 14 of the cooling device 1 (see FIG. 3) until a tolerable tolerance range of the height difference or the heights 8 of the cooling elements 6 is achieved. If part of this height difference is not already taken into account by the shape of the preform 11 (for example by forming regions with different thicknesses 12 following a curve, for example), calibration can be carried out in a correspondingly comprehensive manner. With a preform 11 that already at least partially takes into account a height deviation of the sintered and formed green compact, the work involved in calibration can be reduced.

The calibration tool 22 can also have mold cavities, in which the cooling elements 6 are at least partially received during calibration.

Calibration can take place in one or more stages, optionally with an intermediate relief of the cooling device 1 between the calibration steps.

According to an embodiment, it can also be provided that the heights 8 of the cooling elements 6 are adjusted by pressing material from the head region of the cooling elements 6 (the cooling element heads 7) into a region 23 adjacent to or below the head region of the cooling elements 6. This is shown in exaggerated fashion in FIG. 6. A simple plate tool, in particular the aforementioned calibration tool 22, which is pressed against the cooling elements 6, can be used for pressing.

For calibrating or compressing material, it can be advantageous for the cooling elements 6 to have a height difference between a maximum of 0.2 mm and a maximum of 0.4 mm after forming, i.e. to be produced with relatively minor height differences. This can be done with the aforementioned consideration of the shape of the preform 11, for example. The final height tolerance can be achieved more easily in subsequent operation by means of height calibration.

Calibration renders superfluous machining of the cooling elements 6 to reduce the height tolerance of the cooling elements 6. The type of reduction in the height tolerance, can result in partially mushroom-shaped or (slightly) bulged cooling elements 6, which can also be advantageous with regard to the flow of a cooling fluid flowing around the cooling elements 6 and thus the cooling capacity of the cooling device 1. In addition, reducing the height tolerance can reduce or eliminate residual porosity at the upper end of the cooling elements 6.

As mentioned above, the cooling device 1 can also have cooling elements 6 with a different height 8 from one another. In order to be able to carry out height calibration or calibration in this case as well, the calibration tool can be configured in accordance with the desired height profile of the cooling elements 6 in a stepped manner, for example.

A correspondingly configured calibration tool 22 can also be used to form certain shapes of the cooling elements 6. For this purpose, the calibration tool 22 can have a mating contour in order to form the heads of the cooling elements 6 accordingly, for example, i.e. to provide them with a contour or surface design, such as a rounding, a chamfer, etc., or with a depression, a surface roughness that is greater than the roughness after sintering, etc.

In the event that cooling elements 6 of different heights are formed, a stepped calibration tool 22 can also be used.

The method according to the invention can be used to produce a cooling device 1 for cooling components 2, which are provided with a base element 4 having a first surface 5, and with a cooling structure having cooling elements 6, which is arranged on the base element 4 so as to project beyond the first surface 5. At least some of the cooling elements 6 in the head region can have a higher density than the other cooling elements 6 and/or that at least some of the cooling elements 6 in the head region are a different shape to the other cooling elements 6.

The exemplary embodiments show possible embodiments, yet it should be noted at this point that combinations of the individual embodiments with one another are also possible.

For the sake of good order, it should finally be pointed out that the structure of the cooling device 1 or the forming tool 12 is not necessarily shown to scale for better understanding.

Although only a few embodiments of the present invention have been shown and described, it is to be understood that many changes and modifications may be made thereunto without departing from the spirit and scope of the invention.

### LIST OF REFERENCE NUMERALS

1 Cooling device
2 Component
3 Rear side
4 Base element
5 Surface
6 Cooling element
7 Cooling element head
8 Height
9 Depression
10 Structural element
11 Preform
12 Thickness
13 Edge section
14 Central section
15 Forming tool
16 Perforated plate
17 Recess
18 Punch
19 Partial height
20 Furnace
21 Calibration tool
22 Tool wall
23 Region

What is claimed is:

1. A method for producing a cooling device (1) comprising the steps of providing a material and forming a cooling structure from the material, wherein a sinter powder is used as the material, from which a green compact is produced by pressing, wherein the green compact is sintered into a preform (11), and wherein the cooling structure in the form of cooling elements (6) is produced from the preform (11) by forming, for which a part of the preform (11) is pressed through a forming tool (22), forming being carried out in a plurality of forming steps.

2. The method according to claim 1, wherein the height (8) of the cooling elements (6) above a base element (4) of the cooling structure is increased with at least two of the plurality of forming steps.

3. The method according to claim 1, wherein the same forming tool (22) is used for at least two of the plurality of forming steps.

4. The method according to claim 1, wherein heat treatment of the cooling device (1) is carried out between at least two of the plurality of forming steps.

5. The method according to claim 1, wherein the preform (11) is re-compressed and wherein the cooling structure is partially formed during re-compression.

6. The method according to claim 1, wherein the cooling structure is produced by using a perforated plate (16) as a forming tool (12) or a plurality of perforated plates (16) as forming tools (15) in the form of pin-shaped cooling elements (6).

7. The method according to claim 1, wherein the cooling device (1) is calibrated after the forming steps for producing the cooling elements (6).

8. The method according to claim 7, wherein the height (8) of at least some of the cooling elements (6) is adjusted by pressing material out of the head region of the cooling elements (6) into a region (23) adjacent to or below the head region of the cooling elements (6).

9. A cooling device (1) for cooling components (2) comprising a base element (4) having a first surface (5) and with a cooling structure having cooling elements (6), which is arranged on the base element (4) so as to project beyond the first surface (5), wherein the base element (4) and the cooling elements (6) are composed of a sintered material and wherein the cooling elements (6) are produced from the material of the base element (4) by multi-stage forming.

10. The cooling device (1) according to claim 9, wherein the base element (4) and the cooling elements (6) have a density of at least 98% of the full density of the material used.

11. The cooling device (1) according to claim 9, wherein the cooling elements (6) have a height (8) above the first surface (5) of the base element (4) that is between 4 mm and 40 mm.

12. The cooling device (1) according to claim 9, wherein a rear side (3) of the base element (4) is configured to have a planar surface.

13. The cooling device (1) according to claim 9, wherein at least one further structural element (10) is arranged on the first surface (5) of the base element (4), which protrudes beyond the cooling elements (6) in the direction of the height (8) and which is produced in net-shape or near net-shape quality.

14. The cooling device (1) according to claim 9, wherein at least some of the cooling elements (6) in the head region have a higher density than the other cooling elements (6) and/or wherein at least some of the cooling elements (6) in the head region are a different shape to the other cooling elements (6).
